(19) United States
(12) Patent Application Publication
(10) Pub. No.: US 2009/0170278 A1
(43) Pub. Date: Jul. 2, 2009

(54) METHOD FOR FABRICATING SEMICONDUCTOR DEVICE

(76) Inventor: CHUL GU KANG, Bucheon-si (KR)

Correspondence Address: SALIWANCHIK LLOYD & SALIWANCHIK;A PROFESSIONAL ASSOCIATION, PO Box 142950, GAINESVILLE, FL, 32614, US

(21) Appl. No.: 12/327,109

(22) Filed: Dec. 3, 2008

(30) Foreign Application Priority Data
Dec. 26, 2007 (KR) 10-2007-0137899

(51) Int. Cl. H01L 21/762

(52) U.S. Cl. 438/424; 257/E21.546

(57) ABSTRACT

A method for fabricating a semiconductor device is provided that can comprise: forming a hard mask on a semiconductor substrate; forming a trench by etching the semiconductor substrate using the hard mask; performing a Chemical Mechanical Polishing (CMP) process after insulating film is buried in the trench; removing the hard mask; forming a protective film on the semiconductor substrate including a moat region of the semiconductor substrate adjacent to the insulating film, the moat region being further projected than the insulating film; implanting impurity ion onto the semiconductor substrate on which the protective film is formed; and removing the protective film using cleansing solution through a cleansing process before a gate insulating film is formed in an active region of the semiconductor substrate.

### CROSS-REFERENCE TO RELATED APPLICATION

The present application claims the benefit under 35 U.S.C. §119 of Korean Patent Application No. 10-2007-0137899, filed Dec. 26, 2007, which is hereby incorporated by reference in its entirety.

### BACKGROUND

With the recent increase of integration of a semiconductor device, the size of a device isolation film which isolates one semiconductor device from another semiconductor device is reduced by the same scale so that a device isolation method such as a common LOCOS method has reached the limits of its application.

In a Shallow Trench Isolation (STI) method applied in order to solve the above problems of the LOCOS method, a nitride film having a good etching selectivity with a semiconductor substrate is formed on the semiconductor substrate, and the nitride film is patterned using a photolithography method in order to use the nitride film as a hard mask, thereby forming a nitride pattern.

After the semiconductor substrate is patterned and etched to a predetermined depth using a dry etching method using the nitride pattern as the hard mask, an insulating film is buried in the trench and a STI Chemical Mechanical Polishing (CMP) is then performed to form a device isolation film to be buried in the trench.

Thereafter, the nitride film is removed through a wet etching, and this process is referred to as a moat nitride wet etching.

Meanwhile, when the insulating film is buried in the trench, the insulating film is likely to be deposited more thickly in a peripheral part of wafer compared to a central part of the wafer.

At this time, when a dummy moat is not disposed around a moat region having a narrow width adjacent to the wide device isolation film, the device isolation film is excessively removed, causing a problem that the moat region extends above the device isolation film.

The moat region described above is affected by the subsequent impurity i implantation and cleaning processes and is thus severely damaged to affect other devices.

### BRIEF SUMMARY

Embodiments of the present invention provide a method for fabricating a semiconductor device.

According to embodiments a method is provided for fabricating a semiconductor device which can inhibit a moat region from being damaged.

A method for fabricating a semiconductor device according to an embodiment can comprise: forming a hard mask on a semiconductor substrate; forming a trench by etching the semiconductor substrate using the hard mask, performing a Chemical Mechanical Polishing (CMP) process after an insulating film is buried in the trench and removing the hard mask; forming a protective film on the semiconductor substrate including a moat region of the semiconductor substrate adjacent to the insulating film, where the moat region is further projected than the insulating film; implanting impurity ions onto the semiconductor substrate on which the protective film is formed and performing a cleansing process; and removing the protective film using cleansing solution through a cleansing process before a gate insulating film is formed in an active region of the semiconductor substrate.

### BRIEF DESCRIPTION OF THE DRAWINGS

FIGS. 1 to 4 are views showing a method for fabricating a semiconductor device according to an embodiment of the present invention.

### DETAILED DESCRIPTION

Hereinafter, methods for fabricating a semiconductor device according to embodiments of the present invention will be described with reference to the accompanying drawings.

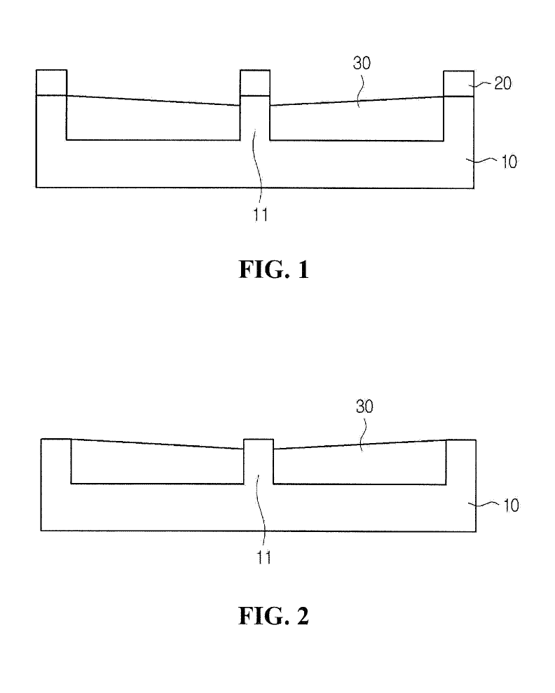

FIGS. 1 to 4 are views showing a method for fabricating a semiconductor device according to an embodiment of the present invention.

Referring to FIG. 1, a nitride film having a good etching selectivity can be formed on a semiconductor substrate 10, and the nitride film can be patterned using a photolithography method in order to use the nitride film as a hard mask, thereby forming a nitride pattern 20.

After the semiconductor substrate is patterned and etched to a predetermined depth using a dry etching method using the nitride pattern 20 as the hard mask, an insulating film can be filled in the trench and a STI Chemical Mechanical Polishing (CMP) can be performed to form a device isolation film buried in the trench.

At this time, when there are device isolation films 30 defining an active region (not shown) and a field region, having a wide area, and a moat region 11 having a narrow width, the device isolation film 30 adjacent to the moat region 11 may be excessively polished so that the moat region 11 is formed having a higher position than the device isolation film 30. That is, a top surface of the moat region 11 extends above the device isolation film 30 adjacent the moat region 11.

Referring to FIG. 2, the nitride pattern 20 used as a hard mask can be removed.

Meanwhile, the moat region 11 may be damaged during a cleansing process after an N-type impurity ion implantation process or a P-type impurity ion implantation process for controlling threshold voltage is performed or during a cleansing process before a gate insulating film is formed, such that the loss of silicon (Si) may occur in the moat region 11 or a pits transition phenomenon may occur.

Furthermore, when polysilicon is deposited on the damaged moat region 11 during the subsequent process of forming a gate electrode, it is possible for the semiconductor device to not operate properly.

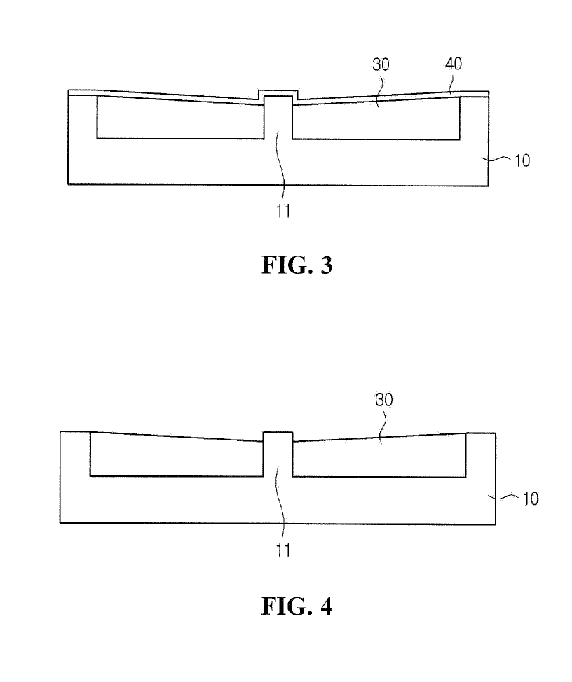

Referring to FIG. 3, according to a method for fabricating a semiconductor device according to an embodiment of the present invention, a protective film 40 can be formed on the substrate 10 including the moat region 11 in order to protect the moat region 11.

Here, the protective film 40 may be an oxide film deposited using a Chemical Vapor Deposition (CVD) method. The protective film 40 can be formed at a thickness of, for example, about 30 Å, to about 50 Å.

The protective film 40 protects the moat region 11 during the cleaning process after the N-type impurity ion or P-type impurity ion implantation process for controlling threshold voltage.

Referring to FIG. 4, a process to form a gate insulating film (not shown) on an active region of the semiconductor substrate 10 after the impurity implantation process and the cleaning process can be performed.

At this time, a cleansing process for the semiconductor substrate 10 can be performed before the gate insulating film is formed, and in this case, the cleansing process is performed using solution mixed with deionized water (DIW) and HF in the ratio of 90:1 to 110:1. The protective film 40 formed on the semiconductor substrate 10 including the moat region 11 can be removed during the cleansing process.

Therefore, the protective film 40 protects the moat region 11 before the gate insulating film is formed in the active region and is able to be removed, not affecting the subsequent process.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for fabricating a semiconductor device, comprising:
forming a hard mask on a semiconductor substrate;
forming a trench by etching the semiconductor substrate using the hard mask;
filling the trench with an insulating film;
performing a Chemical Mechanical Polishing (CMP) process after the insulating film is filled in the trench;
removing the hard mask;
forming a protective film on the semiconductor substrate including a moat region of the semiconductor substrate adjacent to the insulating film, wherein the moat region protrudes above the insulating film in the trench;
implanting impurity ions onto the semiconductor substrate on which the protective film is formed; and
removing the protective film using cleansing solution through a cleansing process before a gate insulating film is formed in an active region of the semiconductor substrate.

2. The method according to claim 1, wherein the hard mask is made of a nitride film.

3. The method according to claim 1, wherein forming the protective film comprises performing a CVD process to deposit an oxide film.

4. The method according to claim 1, wherein the impurity ions are N-type impurity ions or P-type impurity ions for controlling threshold voltage.

5. The method according to claim 1, wherein the protective film is formed to a thickness of about 30 Å to about 50 Å.

6. The method according to claim 1, wherein the cleansing solution is a solution mixed with deionized water (DIW) and HF at the ratio of 90:1 to 110:1.

7. The method according to claim 1, wherein the hard mask is removed after performing the CMP process.
